(19) United States
(12) Patent Application Publication
(10) Pub. No.: US 2005/0130079 A1
(43) Pub. Date: Jun. 16, 2005

(54) Pattern formation method

(75) Inventors: Masayuki Endo, Osaka (JP); Masaru Sasago, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/010,273

(22) Filed: Dec. 14, 2004

(30) Foreign Application Priority Data
Dec. 16, 2003 (JP) 2003-417836

(51) Int. Cl. G03F 7/00

(52) U.S. Cl. 430/327; 430/322

(57) ABSTRACT

In a pattern formation method of this invention, a resist film is formed on a substrate and the resist film is exposed to a solution including a compound having a hydrophilic group. Thereafter, with an immersion liquid provided on the resist film having been exposed to the solution, pattern exposure is performed by selectively irradiating the resist film with exposing light, and the resist film is developed after the pattern exposure. Thus, a resist pattern made of the resist film is formed.

### CROSS-REFERENCE TO RELATED APPLICATIONS

This application claims priority under 35 U.S.C. §119 on Patent Application No. 2003-417836 filed in Japan on Dec. 16, 2003, the entire contents of which are hereby incorporated by reference.

### BACKGROUND OF THE INVENTION

The present invention relates to a pattern formation method for use in fabrication process or the like for semiconductor devices.

In accordance with the increased degree of integration of semiconductor integrated circuits and downsizing of semiconductor devices, there are increasing demands for further rapid development of lithography technique. Currently, pattern formation is carried out through photolithography using exposing light of a mercury lamp, KrF excimer laser, ArF excimer laser or the like, and use of F₂ laser lasing at a shorter wavelength is being examined. However, since there remain a large number of problems in exposure systems and resist materials, photolithography using exposing light of a shorter wavelength has not been put to practical use.

In these circumstances, immersion lithography has been recently proposed for realizing further refinement of patterns by using conventional exposing light (for example, see M. Switkes and M. Rothschild, “Immersion lithography at 157 nm”, J. Vac. Sci. Technol., Vol. B19, p. 2353 (2001)).

In the immersion lithography, a region in an exposure system sandwiched between a projection lens and a resist film formed on a wafer is filled with a liquid having a refractive index n (wherein n>1) and therefore, the NA (numerical aperture) of the exposure system has a value n-NA. As a result, the resolution of the pattern of the resist film can be improved.

Now, a conventional pattern formation method employing the immersion lithography will be described with reference to FIGS. 12A through 12D.

First, a positive chemically amplified resist material having the following composition is prepared:

| | |
|---|---|
| Base polymer: poly((norbornene-5-methylene-t- | 2 g |
| butylcarboxylate) (50 mol %) - (maleic anhydride) (50 mol %)) | |
| Acid generator: triphenylsulfonium triflate | 0.06 g |
| Solvent: propylene glycol monomethyl ether acetate | 20 g |

Next, as shown in FIG. 12A, the aforementioned chemically amplified resist material is applied on a substrate 1 so as to form a resist film 2 with a thickness of 0.35 nm.

Then, as shown in FIG. 12B, with an immersion liquid (water) 3 provided on the resist film 2, pattern exposure is carried out by irradiating the resist film 2 with exposing light 4 of ArF excimer laser with NA of 0.68 through a mask 5.

After the pattern exposure, as shown in FIG. 12C, the resist film 2 is baked with a hot plate at a temperature of 110° C. for 60 seconds, and the resultant resist film is developed with a 2.38 wt % tetramethylammonium hydroxide aqueous solution (alkaline developer). In this manner, a resist pattern 2a made of an unexposed portion of the resist film 2 and having a line width of 0.09 μm is formed as shown in FIG. 12D.

As shown in FIG. 12D, however, the resist pattern 2a formed by the conventional pattern formation method employing the immersion lithography is in a defective shape.

### SUMMARY OF THE INVENTION

The present inventors have variously examined the reason why the resist pattern formed by the conventional immersion lithography is in a defective shape, resulting in finding that it is because the adhesion (wettability) to the resist film 2 of the immersion liquid 3 provided for the immersion lithography on the resist film 2 is poor. Specifically, the immersion liquid 3 provided on the resist film 2 is, for example, not uniformly diffused on the resist film 2 but tends to be present thereon in the form of drops. Therefore, it is difficult to uniformly provide the immersion liquid 3 on an exposure region of the resist film 2. In other words, it is confirmed that the necessary exposure region of the resist film 2 is not sufficiently covered with the immersion liquid 3.

When a resist pattern in such a defective shape is used for etching a target film, the resultant pattern of the target film is also in a defective shape, which disadvantageously lowers the productivity and the yield in the fabrication process for semiconductor devices.

In consideration of the aforementioned conventional problem, an object of the invention is forming a resist pattern in a good shape by employing the immersion lithography.

The present inventors have made various examinations for improving the adhesion to a resist film of an immersion liquid provided on the resist film, resulting in finding that it is effective to perform, before the pattern exposure, a surface treatment for exposing the surface of a resist film to an acid solution, a surface active agent or a solution including a compound having a hydrophilic group such as cyclodextrin. Specifically, before the pattern exposure, a solution including a compound having a hydrophilic group is supplied onto the surface of the resist film, thereby lowering the hydrophobic property of the surface of the resist film, namely, reforming the surface of the resist film to be easily interacted with the immersion liquid. As a result, the immersion liquid provided on the reformed resist film can sufficiently cover the exposure region. In other words, a hydrophilic group is coordinated on the surface of the resist film by supplying a compound having the hydrophilic group. Therefore, the surface of the resist film temporarily exhibits a hydrophilic property, and hence, the affinity is improved owing to the ion interaction with the immersion liquid generally including a large number of hydroxyl groups. As a result, it is possible to avoid the state where the immersion liquid is repelled on the surface of the resist film and cannot be easily uniformly diffused.

Furthermore, the present inventors have confirmed that the hydrophilic property of the surface of the resist film can be improved not only through the surface treatment of the resist film with the hydrophilic solution but also by adding a compound having a hydrophilic group to the resist film so as to make part of the compound having a hydrophilic group coordinate on the resist film.

The present invention was devised on the basis of the aforementioned findings, and according to the invention, the adhesion to a resist film of an immersion liquid provided on the resist film is improved by exposing the surface of the resist film to a solution including a compound having a hydrophilic group or by adding the compound to the resist film or the immersion liquid. Specifically, the present invention is practiced as follows:

The first pattern formation method of this invention includes the steps of forming a resist film on a substrate; exposing the resist film to a solution including a compound having a hydrophilic group; performing pattern exposure by selectively irradiating the resist film with exposing light with an immersion liquid provided on the resist film after exposing the resist film to the solution; and developing the resist film after the pattern exposure.

In the first pattern formation method, the hydrophilic property of the surface of the resist film is improved owing to the compound having a hydrophilic group, and therefore, the adhesion to the resist film of the immersion liquid provided on the resist film in the pattern exposure is improved. Therefore, since a necessary exposure region is sufficiently covered with the immersion liquid provided on the resist film, the immersion liquid definitely transmits the exposing light. As a result, abnormal exposure can be prevented, so that a resist pattern can be formed in a good shape by the immersion lithography.

The second pattern formation method of this invention includes the steps of forming, on a substrate, a resist film including a compound having a hydrophilic group; performing pattern exposure by selectively irradiating the resist film with exposing light with an immersion liquid provided on the resist film; and developing the resist film after the pattern exposure.

In the second pattern formation method, when the immersion liquid is provided on the resist film, part of the compound having a hydrophilic group is coordinated on the surface of the resist film, so that the hydrophilic property of the surface of the resist film can be improved, and therefore, the adhesion to the resist film of the immersion liquid is improved. Therefore, since a necessary exposure region is sufficiently covered with the immersion liquid provided on the resist film, the immersion liquid definitely transmits the exposing light. As a result, abnormal exposure can be prevented, so that a resist pattern can be formed in a good shape by the immersion lithography.

The second pattern formation method preferably further includes, between the step of forming a resist film and the step of performing pattern exposure, a step of exposing the resist film to a solution including a compound having a hydrophilic group. Thus, the hydrophilic property of the surface of the resist film can be further improved, and hence, the adhesion to the resist film of the immersion liquid can be further improved.

In the first or second pattern formation method, the compound having a hydrophilic group is preferably an acid compound, a surface active agent or cyclodextrin. At this point, it is known that cyclodextrin is a cyclic oligosaccharide and has a plurality of hydroxyl groups (—OH) around.

Furthermore, the surface active agent is preferably a cationic surface active agent or a nonionic surface active agent.

In the first or second pattern formation method, the immersion liquid is preferably water.

In the first or second pattern formation method, a puddle method, a dip method or a spray method may be employed in the step of exposing the resist film to a solution including a compound having a hydrophilic group.

The third pattern formation method of this invention includes the steps of forming a resist film on a substrate; performing pattern exposure by selectively irradiating the resist film with exposing light with an immersion liquid including cyclodextrin provided on the resist film; and developing the resist film after the pattern exposure.

In the third pattern formation method, since the immersion liquid provided on the resist film includes cyclodextrin, the hydrophilic property of the surface of the resist film is improved owing to a hydrophilic group of the cyclodextrin, and therefore, the adhesion to the resist film of the immersion liquid is improved. Therefore, since a necessary exposure region is sufficiently covered with the immersion liquid provided on the resist film, the immersion liquid definitely transmits the exposing light. As a result, abnormal exposure can be prevented, so that a resist pattern can be formed in a good shape by the immersion lithography. In the third pattern formation method, the immersion liquid preferably includes water.

The concentration of the acid compound or the surface active agent is appropriately approximately 10⁻⁴ wt % or more and 10⁻² wt % or less, which does not limit the invention.

Also, the concentration of cyclodextrin is appropriately approximately 10⁻³ wt % or more and 1 wt % or less, which does not limit the invention.

### BRIEF DESCRIPTION OF THE DRAWINGS

FIGS. 1A, 1B and 1C are cross-sectional views for showing procedures in a pattern formation method according to Embodiment 1 of the invention;

FIGS. 2A and 2B are cross-sectional views for showing other procedures in the pattern formation method of Embodiment 1;

FIGS. 3A and 3B are diagrams for showing the adhesion between a resist film and an immersion liquid, and specifically, FIG. 3A is a cross-sectional view obtained when the adhesion is low and FIG. 3B is a cross-sectional view obtained when the adhesion is high;

FIGS. 4A, 4B and 4C are cross-sectional views for showing procedures in a pattern formation method according to Embodiment 2 of the invention;

FIGS. 5A and 5B are cross-sectional views for showing other procedures in the pattern formation method of Embodiment 2;

FIGS. 6A, 6B and 6C are cross-sectional views for showing procedures in a pattern formation method according to Embodiment 3 of the invention;

FIGS. 7A and 7B are cross-sectional views for showing other procedures in the pattern formation method of Embodiment 3;

FIGS. 8A, 8B, 8C and 8D are cross-sectional views for showing procedures in a pattern formation method according to Embodiment 4 of the invention;

FIGS. 9A, 9B, 9C and 9D are cross-sectional views for showing procedures in a pattern formation method according to Embodiment 5 of the invention;

FIGS. 10A, 10B, 10C and 10D are cross-sectional views for showing procedures in a pattern formation method according to Embodiment 6 of the invention;

FIGS. 11A, 11B, 11C and 11D are cross-sectional views for showing procedures in a pattern formation method according to Embodiment 7 of the invention; and

FIGS. 12A, 12B, 12C and 12D are cross-sectional views for showing procedures in a conventional pattern formation method.

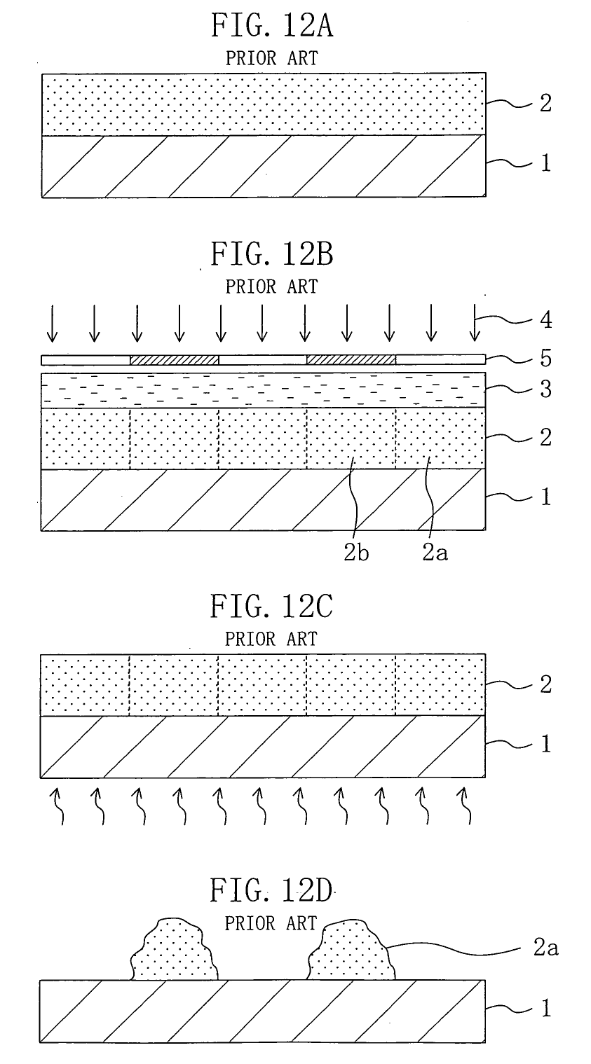

### DETAILED DESCRIPTION OF THE INVENTION

### EMBODIMENT 1

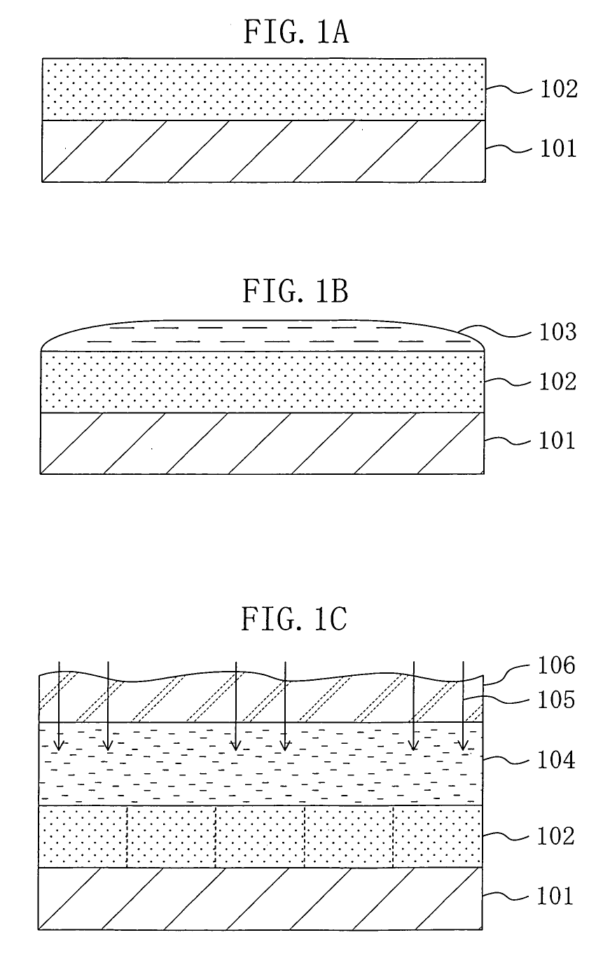

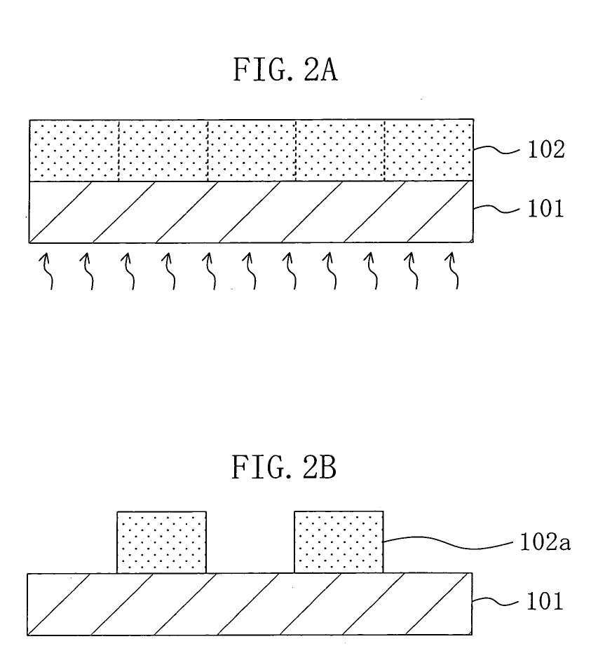

A pattern formation method according to Embodiment 1 of the invention will now be described with reference to FIGS. 1A through 1C, 2A and 2B.

First, a positive chemically amplified resist material having the following composition is prepared:

| | |
|---|---|
| Base polymer: poly((norbornene-5-methylene-t- | 2 g |
| butylcarboxylate) (50 mol %) - (maleic anhydride) (50 mol %)) | |
| Acid generator: triphenylsulfonium triflate | 0.06 g |
| Solvent: propylene glycol monomethyl ether acetate | 20 g |

Next, as shown in FIG. 1A, the aforementioned chemically amplified resist material is applied on a substrate 101 so as to form a resist film 102 with a thickness of 0.35 μm.

Then, as shown in FIG. 1B, a surface reforming treatment for improving the hydrophilic property of the surface of the resist film 102 is performed by exposing the surface of the resist film 102 to an aqueous solution 103 of acetic acid with a concentration of approximately 3×10⁻³ wt % for 15 seconds by, for example, a puddle method.

Next, as shown in FIG. 1C, with an immersion liquid 104 of water provided between the resist film 102 and a projection lens 106, pattern exposure is carried out by irradiating the resist film 102 with exposing light 105 of ArF excimer laser with NA of 0.68 through a mask (not shown).

After the pattern exposure, as shown in FIG. 2A, the resist film 102 is baked with a hot plate at a temperature of 110° C. for 60 seconds, and the resultant resist film is developed with a 2.38 wt % tetramethylammonium hydroxide aqueous solution (alkaline developer). In this manner, a resist pattern 102a made of an unexposed portion of the resist film 102 and having a line width of 0.09 μm is formed as shown in FIG. 2B.

In this manner, according to the pattern formation method of Embodiment 1, the surface of the resist film 102 is exposed to the aqueous solution 103 of acetic acid having a carboxyl group (—COOH), that is, a hydrophilic group, before the pattern exposure, and hence, the hydrophilic property of the surface of the resist film 102 is improved by the carboxyl group. Therefore, the adhesion to the resist film 102 of the immersion liquid 104 provided on the resist film 102 in the pattern exposure can be improved. Accordingly, a necessary exposure region can be sufficiently covered with the immersion liquid 104 provided on the resist film 102, and hence, the immersion liquid 104 definitely transmits the exposing light 105. As a result, the resist pattern 102a made of the resist film 102 can be formed in a good shape by the immersion lithography.

The acid compound included in the aqueous solution 103 is not limited to acetic acid but may be trifluoromethylsulfonic acid, nonafluorobutylsulfonic acid, perfluorooctylsulfonic acid or the like.

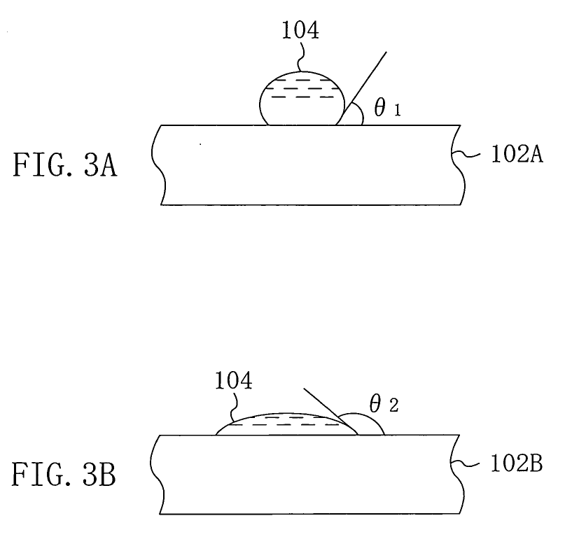

FIG. 3A shows a contact angle θ₁ of an immersion liquid 104 against a first resist film 102A on the first resist film 102A having comparatively low affinity against the immersion liquid 104, and FIG. 3B shows a contact angle θ₂ of an immersion liquid 104 against a second resist film 102B on the second resist film 102B having affinity against the immersion liquid 104 higher than the first resist film 102A. In this case, a contact angle θ means an angle between the surface of a resist film and the liquid surface of an immersion liquid at the boundary therebetween.

As shown in FIGS. 3A and 3B, as the affinity between the immersion liquid 104 and the second resist film 102B is higher, the contact angle θ of the immersion liquid against the surface of the resist film is larger (i.e., θ₂>>θ₁). Thus, a difference in the contact angle θ corresponds to a difference in the affinity between the immersion liquid and the resist film.

### EMBODIMENT 2

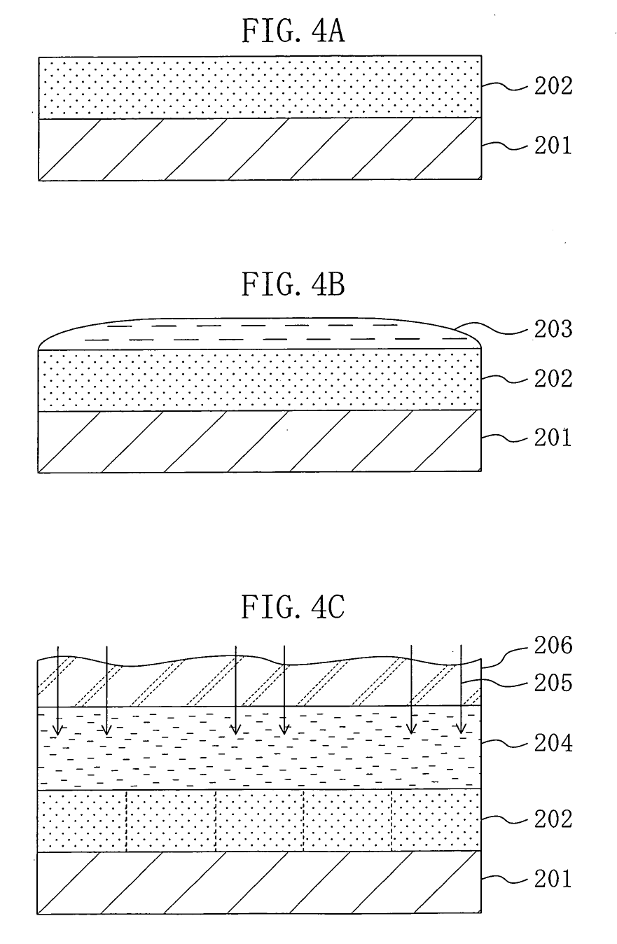

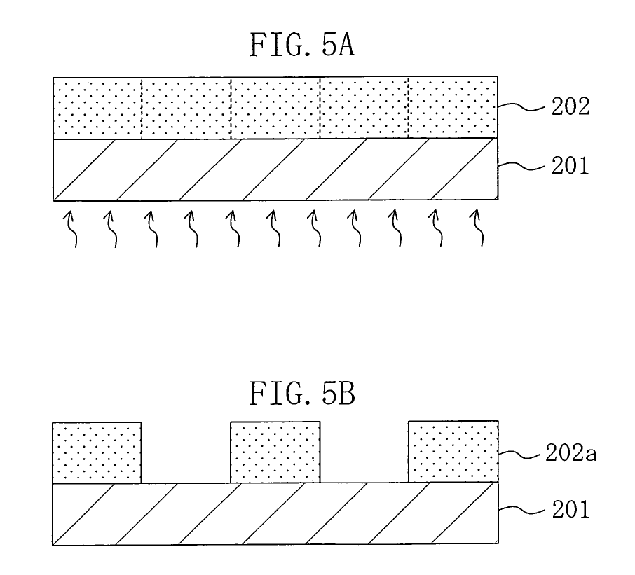

A pattern formation method according to Embodiment 2 of the invention will now be described with reference to FIGS. 4A through 4C, 5A and 5B.

First, a positive chemically amplified resist material having the following composition is prepared:

| | |
|---|---|
| Base polymer: poly((norbornene-5-methylene-t- | 2 g |
| butylcarboxylate) (50 mol %) - (maleic anhydride) (50 mol %)) | |
| Acid generator: triphenylsulfonium triflate | 0.06 g |
| Solvent: propylene glycol monomethyl ether acetate | 20 g |

Next, as shown in FIG. 4A, the aforementioned chemically amplified resist material is applied on a substrate 201 so as to form a resist film 202 with a thickness of 0.35 μm.

Then, as shown in FIG. 4B, the surface reforming treatment for improving the hydrophilic property of the surface of the resist film 202 is performed by exposing the surface of the resist film 202 to an aqueous solution 203 of benzylmethylammonium chloride, that is, a surface active agent, with a concentration of approximately 7×10⁻³ wt % for 30 seconds by, for example, the puddle method.

Next, as shown in FIG. 4C, with an immersion liquid 204 of water provided between the resist film 202 and a projection lens 206, pattern exposure is carried out by irradiating the resist film 202 with exposing light 205 of ArF excimer laser with NA of 0.68 through a mask (not shown).

After the pattern exposure, as shown in FIG. 5A, the resist film 202 is baked with a hot plate at a temperature of 110° C. for 60 seconds, and the resultant resist film is developed with a 2.38 wt % tetramethylammonium hydroxide aqueous solution (alkaline developer). In this manner, a resist pattern 202a made of an unexposed portion of the resist film 202 and having a line width of 0.09 μm is formed as shown in FIG. 5B.

In this manner, according to the pattern formation method of Embodiment 2, the surface of the resist film 202 is exposed to the aqueous solution 203 of benzylmethylammonium chloride, that is, a surface active agent, before the pattern exposure, and hence, the hydrophilic property of the surface of the resist film 202 is improved by a hydrophilic group of the surface active agent. Therefore, the adhesion to the resist film 202 of the immersion liquid 204 provided on the resist film 202 in the pattern exposure can be improved. Accordingly, a necessary exposure region can be sufficiently covered with the immersion liquid 204 provided on the resist film 202, and hence, the immersion liquid 204 definitely transmits the exposing light 205. As a result, the resist pattern 202a made of the resist film 202 can be formed in a good shape by the immersion lithography.

The surface active agent included in the aqueous solution 203 may be a nonionic surface active agent instead of benzylmethylammonium chloride, that is, a cationic surface active agent.

Examples of the cationic surface active agent are, apart from benzylmethylammonium chloride, cetylmethylammonium chloride, stearylmethylammonium chloride, cetyltrimethylammonium chloride, stearyltrimethylammonium chloride, distearyldimethylammonium chloride, stearyldimethylbenzylammonium chloride, dodecylmethylammonium chloride, dodecyltrimethylammonium chloride, benzyltrimethylammonium chloride, and benzalkonium chloride.

Also, examples of the nonionic surface active agent are nonyl phenol ethoxylate, octylphenyl polyoxyethylene ether, lauryl polyoxyethylene ether, cetyl polyoxyethylene ether, sucrose fatty ester, polyoxyethylene lanolin fatty ester, polyoxyethylene sorbitan fatty ester, polyoxyethylene glycol mono fatty ester, fatty monoethanolamide, fatty diethanolamide and fatty triethanolamide.

### EMBODIMENT 3

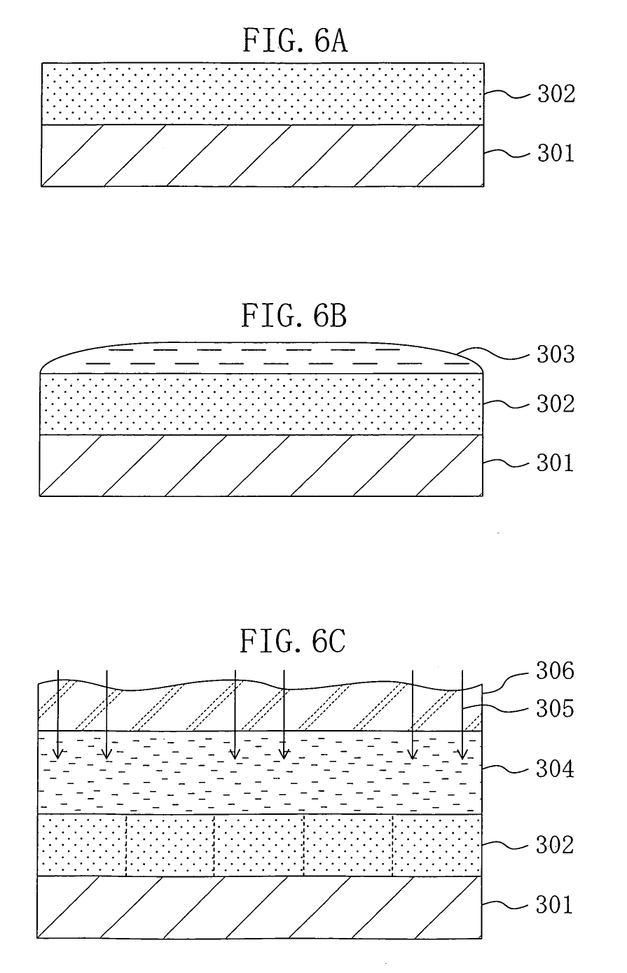

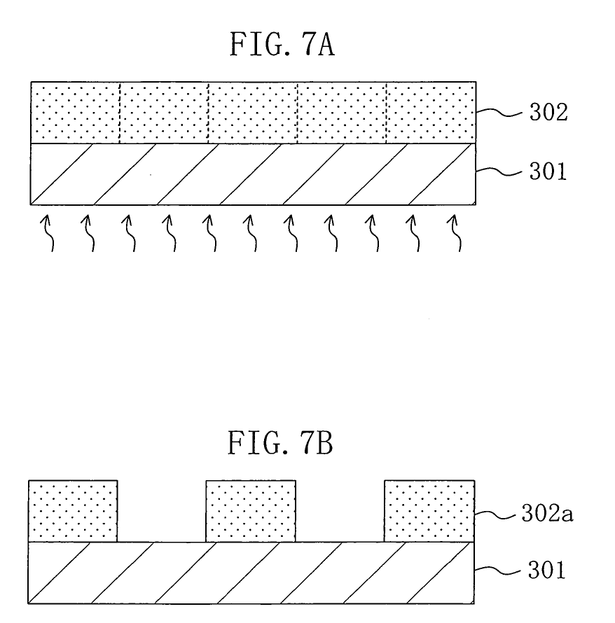

A pattern formation method according to Embodiment 3 of the invention will now be described with reference to FIGS. 6A through 6C, 7A and 7B.

First, a positive chemically amplified resist material having the following composition is prepared:

| | |
|---|---|
| Base polymer: poly((norbornene-5-methylene-t- | 2 g |
| butylcarboxylate) (50 mol %) - (maleic anhydride) (50 mol %)) | |
| Acid generator: triphenylsulfonium triflate | 0.06 g |
| Solvent: propylene glycol monomethyl ether acetate | 20 g |

Next, as shown in FIG. 6A, the aforementioned chemically amplified resist material is applied on a substrate 301 so as to form a resist film 302 with a thickness of 0.35 μm.

Then, as shown in FIG. 6B, the surface reforming treatment for improving the hydrophilic property of the surface of the resist film 302 is performed by exposing the surface of the resist film 302 to an aqueous solution 303 of α-cyclodextrin with a concentration of approximately 5×10⁻³ wt % for 25 seconds by, for example, the puddle method.

Next, as shown in FIG. 6C, with an immersion liquid 304 of water provided between the resist film 302 and a projection lens 306, pattern exposure is carried out by irradiating the resist film 302 with exposing light 305 of ArF excimer laser with NA of 0.68 through a mask (not shown).

After the pattern exposure, as shown in FIG. 7A, the resist film 302 is baked with a hot plate at a temperature of 110° C. for 60 seconds, and the resultant resist film is developed with a 2.38 wt % tetramethylammonium hydroxide aqueous solution (alkaline developer). In this manner, a resist pattern 302a made of an unexposed portion of the resist film 302 and having a line width of 0.09 μm is formed as shown in FIG. 7B.

In this manner, according to the pattern formation method of Embodiment 3, the surface of the resist film 302 is exposed to the aqueous solution 303 of cyclodextrin having a hydroxyl group (—OH) before the pattern exposure, and hence, the hydrophilic property of the surface of the resist film 302 is improved owing to the hydroxyl group of the cyclodextrin. Therefore, the adhesion to the resist film 302 of the immersion liquid 304 provided on the resist film 302 in the pattern exposure can be improved. Accordingly, a necessary exposure region can be sufficiently covered with the immersion liquid 304 provided on the resist film 302, and hence, the immersion liquid 304 definitely transmits the exposing light 305. As a result, the resist pattern 302a made of the resist film 302 can be formed in a good shape by the immersion lithography.

The cyclodextrin included in the aqueous solution 303 is not limited to α-cyclodextrin but may be β-cyclodextrin, γ-cyclodextrin, δ-cyclodextrin or the like.

### EMBODIMENT 4

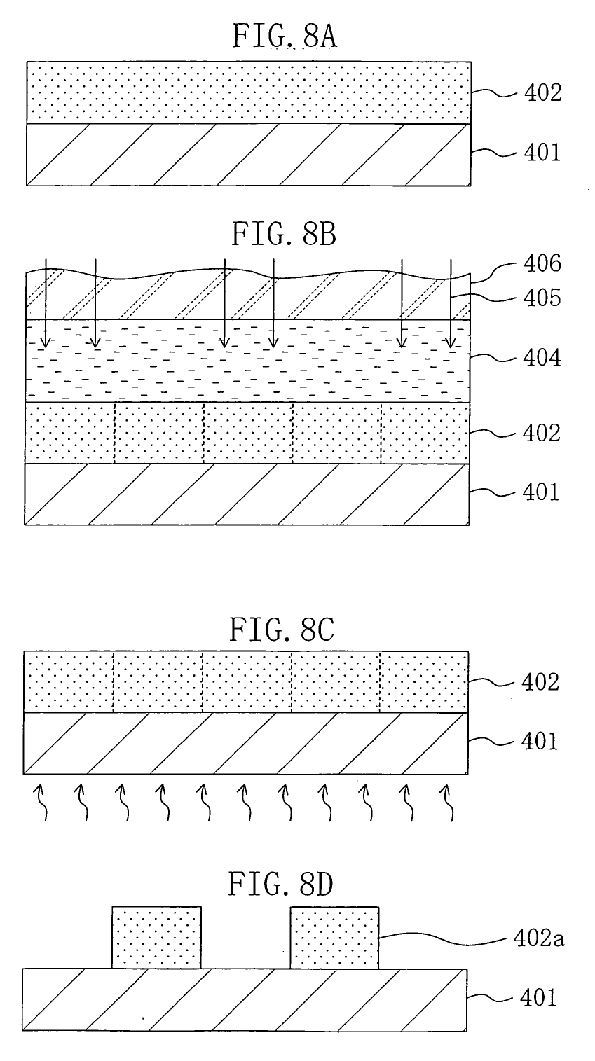

A pattern formation method according to Embodiment 4 of the invention will now be described with reference to FIGS. 8A through 8D.

First, a positive chemically amplified resist material having the following composition is prepared:

| | |
|---|---|
| Base polymer: poly((norbornene-5-methylene-t- | 2 g |
| butylcarboxylate) (50 mol %) - (maleic anhydride) (50 mol %)) | |
| Acid generator: triphenylsulfonium triflate | 0.06 g |
| Acid compound: acetic acid | 0.05 g |
| Solvent: propylene glycol monomethyl ether acetate | 20 g |

Next, as shown in FIG. 8A, the aforementioned chemically amplified resist material is applied on a substrate 401 so as to form a resist film 402 with a thickness of 0.35 μm.

Then, as shown in FIG. 8B, with an immersion liquid 404 of water provided between the resist film 402 and a projection lens 406, pattern exposure is carried out by irradiating the resist film 402 with exposing light 405 of ArF excimer laser with NA of 0.68 through a mask (not shown).

After the pattern exposure, as shown in FIG. 8C, the resist film 402 is baked with a hot plate at a temperature of 110° C. for 60 seconds, and the resultant resist film is developed with a 2.38 wt % tetramethylammonium hydroxide aqueous solution (alkaline developer). In this manner, a resist pattern 402a made of an unexposed portion of the resist film 402 and having a line width of 0.09 μm is formed as shown in FIG. 8D.

In this manner, according to the pattern formation method of Embodiment 4, the resist film 402 includes acetic acid, and hence, the hydrophilic property of the surface of the resist film 402 is improved owing to a carboxyl group of the included acetic acid. Therefore, the adhesion to the resist film 402 of the immersion liquid 404 provided on the resist film 402 in the pattern exposure can be improved. Accordingly, a necessary exposure region can be sufficiently covered with the immersion liquid 404 provided on the resist film 402, and hence, the immersion liquid 404 definitely transmits the exposing light 405. As a result, the resist pattern 402a made of the resist film 402 can be formed in a good shape by the immersion lithography.

The acid compound included in the resist film 402 is not limited to acetic acid but may be trifluoromethylsulfonic acid, nonafluorobutylsulfonic acid, perfluorooctylsulfonic acid or the like.

### EMBODIMENT 5

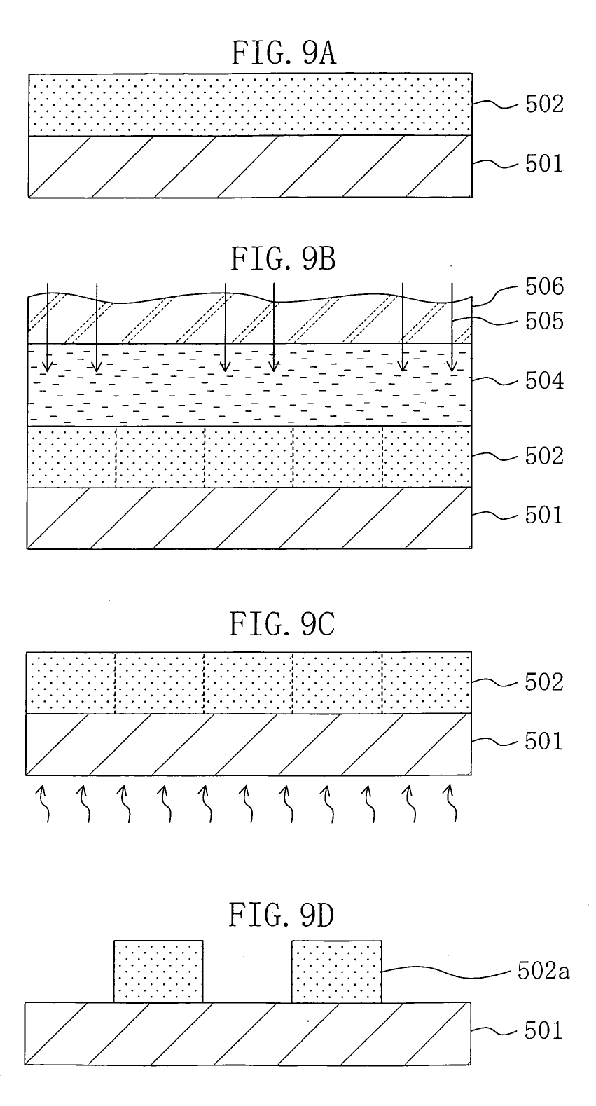

A pattern formation method according to Embodiment 5 of the invention will now be described with reference to FIGS. 9A through 9D.

First, a positive chemically amplified resist material having the following composition is prepared:

| | |
|---|---|
| Base polymer: poly((norbornene-5-methylene-t- | 2 g |
| butylcarboxylate) (50 mol %) - (maleic anhydride) (50 mol %)) | |
| Acid generator: triphenylsulfonium triflate | 0.06 g |
| Surface active agent: octylphenyl polyoxyethylene ether | 0.07 g |
| Solvent: propylene glycol monomethyl ether acetate | 20 g |

Next, as shown in FIG. 9A, the aforementioned chemically amplified resist material is applied on a substrate 501 so as to form a resist film 502 with a thickness of 0.35 μm.

Then, as shown in FIG. 9B, with an immersion liquid 504 of water provided between the resist film 502 and a projection lens 506, pattern exposure is carried out by irradiating the resist film 502 with exposing light 505 of ArF excimer laser with NA of 0.68 through a mask (not shown).

After the pattern exposure, as shown in FIG. 9C, the resist film 502 is baked with a hot plate at a temperature of 110° C. for 60 seconds, and the resultant resist film is developed with a 2.38 wt % tetramethylammonium hydroxide aqueous solution (alkaline developer). In this manner, a resist pattern 502a made of an unexposed portion of the resist film 502 and having a line width of 0.09 μm is formed as shown in FIG. 9D.

In this manner, according to the pattern formation method of Embodiment 5, the resist film 502 includes octylphenyl polyoxyethylene ether, that is, a nonionic surface active agent, and hence, the hydrophilic property of the surface of the resist film 502 is improved owing to a hydrophilic group of the included surface active agent. Therefore, the adhesion to the resist film 502 of the immersion liquid 504 provided on the resist film 502 in the pattern exposure can be improved. Accordingly, a necessary exposure region can be sufficiently covered with the immersion liquid 504 provided on the resist film 502, and hence, the immersion liquid 504 definitely transmits the exposing light 505. As a result, the resist pattern 502a made of the resist film 502 can be formed in a good shape by the immersion lithography.

The surface active agent included in the resist film 502 is not limited to octylphenyl polyoxyethylene ether but may be any of the cationic surface active agents and the nonionic surface active agents described in Embodiment 2.

### EMBODIMENT 6

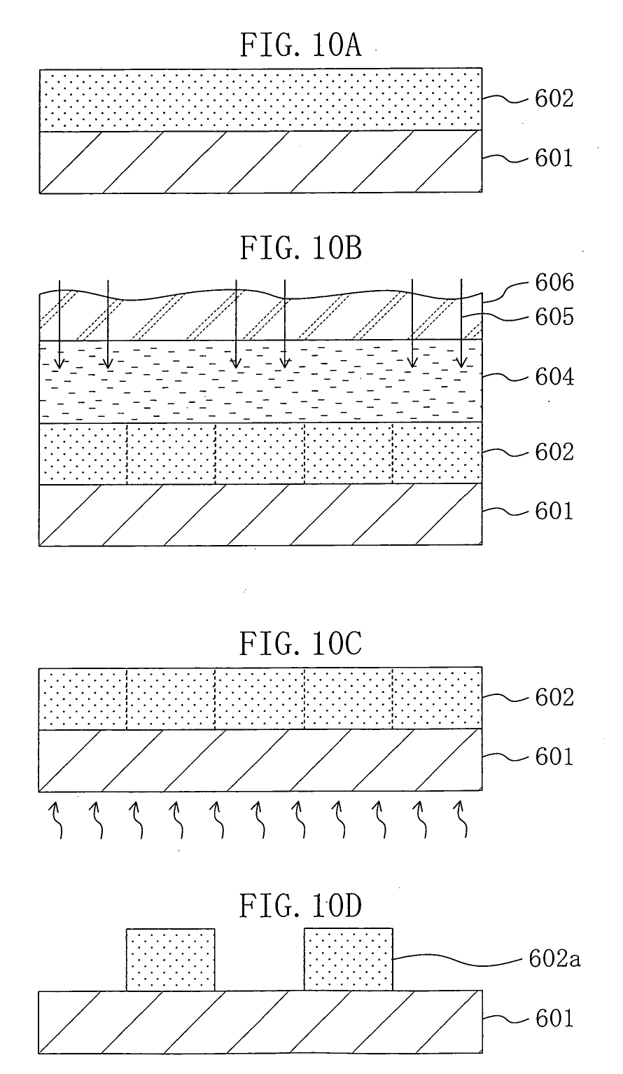

A pattern formation method according to Embodiment 6 of the invention will now be described with reference to FIGS. 10A through 10D.

First, a positive chemically amplified resist material having the following composition is prepared:

| | |
|---|---|
| Base polymer: poly((norbornene-5-methylene-t- | 2 g |
| butylcarboxylate) (50 mol %) - (maleic anhydride) (50 mol %)) | |
| Acid generator: triphenylsulfonium triflate | 0.06 g |
| Compound having hydrophilic group: β-cyclodextrin | 0.05 g |
| Solvent: propylene glycol monomethyl ether acetate | 20 g |

Next, as shown in FIG. 10A, the aforementioned chemically amplified resist material is applied on a substrate 601 so as to form a resist film 602 with a thickness of 0.35 μm.

Then, as shown in FIG. 10B, with an immersion liquid 604 of water provided between the resist film 602 and a projection lens 606, pattern exposure is carried out by irradiating the resist film 602 with exposing light 605 of ArF excimer laser with NA of 0.68 through a mask (not shown).

After the pattern exposure, as shown in FIG. 10C, the resist film 602 is baked with a hot plate at a temperature of 110° C. for 60 seconds, and the resultant resist film is developed with a 2.38 wt % tetramethylammonium hydroxide aqueous solution (alkaline developer). In this manner, a resist pattern 602a made of an unexposed portion of the resist film 602 and having a line width of 0.09 μm is formed as shown in FIG. 10D.

In this manner, according to the pattern formation method of Embodiment 6, the resist film 602 includes cyclodextrin having a hydroxyl group, and hence, the hydrophilic property of the surface of the resist film 602 is improved owing to the hydroxyl group of the cyclodextrin. Therefore, the adhesion to the resist film 602 of the immersion liquid 604 provided on the resist film 602 in the pattern exposure can be improved. Accordingly, a necessary exposure region can be sufficiently covered with the immersion liquid 604 provided on the resist film 602, and hence, the immersion liquid 604 definitely transmits the exposing light 605. As a result, the resist pattern 602a made of the resist film 602 can be formed in a good shape by the immersion lithography.

The cyclodextrin included in the resist film 602 is not limited to β-cyclodextrin but may be α-cyclodextrin, γ-cyclodextrin, δ-cyclodextrin or the like.

Furthermore, also in each of Embodiments 4 through 6, not only the compound having a hydrophilic group is included in the resist material but also a surface reforming treatment for further improving the hydrophilic property between the surface of the resist film and the immersion liquid may be performed by exposing the surface of the obtained resist film to an aqueous solution including a compound having a hydrophilic group, namely, an aqueous solution including an acid compound, a surface active agent or cyclodextrin.

### EMBODIMENT 7

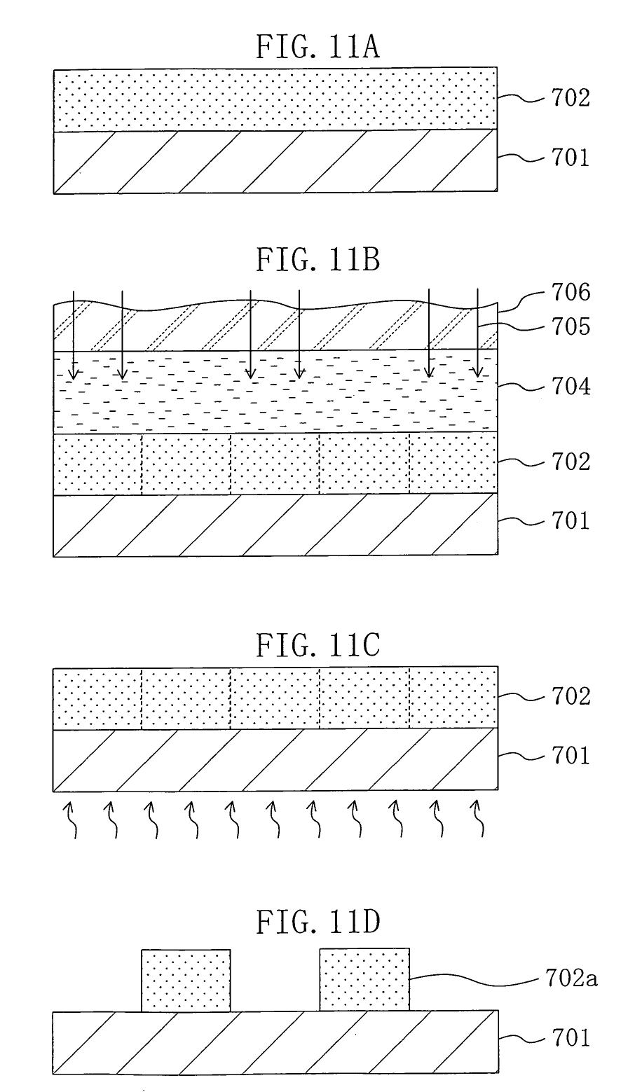

A pattern formation method according to Embodiment 7 of the invention will now be described with reference to FIGS. 11A through 11D.

First, a positive chemically amplified resist material having the following composition is prepared:

| | |
|---|---|
| Base polymer: poly((norbornene-5-methylene-t- | 2 g |
| butylcarboxylate) (50 mol %) - (maleic anhydride) (50 mol %)) | |
| Acid generator: triphenylsulfonium triflate | 0.06 g |
| Solvent: propylene glycol monomethyl ether acetate | 20 g |

Next, as shown in FIG. 11A, the aforementioned chemically amplified resist material is applied on a substrate 701 so as to form a resist film 702 with a thickness of 0.35 μm.

Then, as shown in FIG. 11B, with an immersion liquid 704 of an aqueous solution including γ-cyclodextrin with a concentration of approximately 3×10⁻² wt % provided between the resist film 702 and a projection lens 706, pattern exposure is carried out by irradiating the resist film 702 with exposing light 705 of ArF excimer laser with NA of 0.68 through a mask (not shown).

After the pattern exposure, as shown in FIG. 11C, the resist film 702 is baked with a hot plate at a temperature of 110° C. for 60 seconds, and the resultant resist film is developed with a 2.38 wt % tetramethylammonium hydroxide aqueous solution (alkaline developer). In this manner, a resist pattern 702a made of an unexposed portion of the resist film 702 and having a line width of 0.09 μm is formed as shown in FIG. 11D.

In this manner, according to the pattern formation method of Embodiment 7, the immersion liquid 704 includes cyclodextrin having a hydroxyl group, and hence, the cyclodextrin is coordinated on the surface of the resist film 702 so as to improve the hydrophilic property of the surface of the resist film 702 owing to the hydroxyl group. Therefore, the adhesion to the resist film 702 of the immersion liquid 704 provided on the resist film 702 in the pattern exposure can be improved. Accordingly, a necessary exposure region can be sufficiently covered with the immersion liquid 704 provided on the resist film 702, and hence, the immersion liquid 704 definitely transmits the exposing light 705. As a result, the resist pattern 702a made of the resist film 702 can be formed in a good shape by the immersion lithography.

The cyclodextrin included in the immersion liquid 704 is not limited to γ-cyclodextrin but may be α-cyclodextrin, β-cyclodextrin, δ-cyclodextrin or the like.

Also in Embodiment 7, not only the cyclodextrin is included in the immersion liquid 704 but also the hydrophilic property between the surface of the resist film and the immersion liquid may be further improved by exposing, before the pattern exposure, the surface of the resist film to an aqueous solution including a compound having a hydrophilic group, namely, an aqueous solution including an acid compound, a surface active agent or cyclodextrin, or by adding such a compound having a hydrophilic group to the resist material.

On the contrary, also in each of Embodiments 1 through 6, a compound having a hydrophilic group may be included in the immersion liquid.

The method employed for exposing the surface of the resist film to the aqueous solution including the compound having a hydrophilic group is not limited to the puddle method but may be a dip method or a spray method.

A positive chemically amplified resist is used as the resist material in each embodiment, which does not limit invention, and it goes without saying that the invention is applicable to a negative resist material.

Also, the exposing light used in the pattern exposure is not limited to the ArF excimer laser but may be KrF excimer laser, F₂ laser, KrAr laser or Ar₂ laser.

As described so far, in the pattern formation method of this invention, the adhesion to a resist film of an immersion liquid provided on the resist film is improved so as to prevent abnormal exposure, resulting in forming a resist pattern in a good shape. Therefore, the invention is useful as a pattern formation method for use in fabrication process for semiconductor devices.

1. A pattern formation method comprising the steps of:
forming a resist film on a substrate;
exposing said resist film to a solution including a compound having a hydrophilic group;
performing pattern exposure by selectively irradiating said resist film with exposing light with an immersion liquid provided on said resist film after exposing said resist film to said solution; and
developing said resist film after the pattern exposure.

2. The pattern formation method of claim 1,
wherein said compound having a hydrophilic group is an acid compound, a surface active agent or cyclodextrin.

3. The pattern formation method of claim 2,
wherein said surface active agent is a cationic surface active agent or a nonionic surface active agent.

4. The pattern formation method of claim 3,
wherein said cationic surface active agent is cetylmethylammonium chloride, stearylmethylammonium chloride, cetyltrimethylammonium chloride, stearyltrimethylammonium chloride, distearyldimethylammonium chloride, stearyldimethylbenzylammonium chloride, dodecylmethylammonium chloride, dodecyltrimethylammonium chloride, benzylmethylammonium chloride, benzyltrimethylammonium chloride or benzalkonium chloride.

5. The pattern formation method of claim 3,
wherein said nonionic surface active agent is nonyl phenol ethoxylate, octylphenyl polyoxyethylene ether, lauryl polyoxyethylene ether, cetyl polyoxyethylene ether, sucrose fatty ester, polyoxyethylene lanolin fatty ester, polyoxyethylene sorbitan fatty ester, polyoxyethylene glycol mono fatty ester, fatty monoethanolamide, fatty dietanolamide or fatty triethanolamide.

6. The pattern formation method of claim 1,
wherein said immersion liquid is water.

7. The pattern formation method of claim 1,
wherein a puddle method, a dip method or a spray method is employed in the step of exposing said resist film to a solution including a compound having a hydrophilic group.

8. The pattern formation method of claim 1,
wherein said exposing light is KrF excimer laser, ArF excimer laser, F₂ laser, ArKr laser or Ar₂ laser.

9. A pattern formation method comprising the steps of:
forming, on a substrate, a resist film including a compound having a hydrophilic group;
performing pattern exposure by selectively irradiating said resist film with exposing light with an immersion liquid provided on said resist film; and
developing said resist film after the pattern exposure.

10. The pattern formation method of claim 9, further comprising, between the step of forming a resist film and the step of performing pattern exposure, a step of exposing said resist film to a solution including a compound having a hydrophilic group.

11. The pattern formation method of claim 9,
wherein said compound having a hydrophilic group is an acid compound, a surface active agent or cyclodextrin.

12. The pattern formation method of claim 11,
wherein said surface active agent is a cationic surface active agent or a nonionic surface active agent.

13. The pattern formation method of claim 12,
wherein said cationic surface active agent is cetylmethylammonium chloride, stearylmethylammonium chloride, cetyltrimethylammonium chloride, stearyltrimethylammonium chloride, distearyldimethylammonium chloride, stearyldimethylbenzylammonium chloride, dodecylmethylammonium chloride, dodecyltrimethylammonium chloride, benzylmethylammonium chloride, benzyltrimethylammonium chloride or benzalkonium chloride.

14. The pattern formation method of claim 12,
wherein said nonionic surface active agent is nonyl phenol ethoxylate, octylphenyl polyoxyethylene ether, lauryl polyoxyethylene ether, cetyl polyoxyethylene ether, sucrose fatty ester, polyoxyethylene lanolin fatty ester, polyoxyethylene sorbitan fatty ester, polyoxyethylene glycol mono fatty ester, fatty monoethanolamide, fatty dietanolamide or fatty triethanolamide.

15. The pattern formation method of claim 9,
wherein said immersion liquid is water.

16. The pattern formation method of claim 9,
wherein a puddle method, a dip method or a spray method is employed in the step of exposing said resist film to a solution including a compound having a hydrophilic group.

17. The pattern formation method of claim 9,
wherein said exposing light is KrF excimer laser, ArF excimer laser, F₂ laser, ArKr laser or Ar₂ laser.

18. A pattern formation method comprising the steps of:
forming a resist film on a substrate;
performing pattern exposure by selectively irradiating said resist film with exposing light with an immersion liquid including cyclodextrin provided on said resist film; and
developing said resist film after the pattern exposure.

19. The pattern formation method of claim 18,
wherein said immersion liquid includes water.

20. The pattern formation method of claim 18,
wherein said exposing light is KrF excimer laser, ArF excimer laser, F₂ laser, ArKr laser or Ar₂ laser.
